(19) United States
(12) Patent Application Publication
(10) Pub. No.: US 2026/0259510 A1
(43) Pub. Date: Sep. 3, 2026

(54) POSITIONING SYSTEM AND METHOD OF FORMING THE SAME

(71) Applicant: Agency for Science, Technology and Research, Singapore (SG)

(72) Inventors: Zeng Wang, Singapore (SG); Jinghua Teng, Singapore (SG); Mengting Jiang, Singapore (SG)

(21) Appl. No.: 19/163,690

(22) PCT Filed: Mar. 10, 2023
(86) PCT No.: PCT/SG2023/050152

§ 371 Date: Sep. 9, 2025

(51) Int. Cl. G03F 7/00; G03F 9/00

(52) U.S. Cl. CPC G03F 7/70775; G03F 7/70258; G03F 7/70725; G03F 9/7034; G03F 9/7073

(57) ABSTRACT

Various embodiments may relate to a positioning system. The positioning system may include a camera and a computer vision system coupled to the camera. The positioning system may also include an objective and a first piezoelectric stage connected to the objective. The positioning system may also include a second piezoelectric stage configured to hold a mask or two dimensional (2D) lens such that the objective is between the camera and the mask or two dimensional (2D) lens. The positioning system may further include a third piezoelectric stage for holding a sample.

### TECHNICAL FIELD

Various embodiments of this disclosure may relate to a positioning system. Various embodiments of this disclosure may relate to a method of forming a positioning system.

### BACKGROUND

Nano-positioning is a critical step in many applications, such as imaging and micro-nano fabrications. Interferometric techniques are commonly used for applications involving two dimensional (2D) lens or mask. Nano-positioning and alignment techniques have been developed based on interferometry, such as scanning white light interferometry (SWLI) and interferometric-spatial-phase-imaging (ISPI) systems, which rely on interferometric feedback of either lasers or white light. While interferometric techniques can provide sub-nanometre accuracy, the limitation of the accuracy and the repeatability of the motion system may make it difficult to realize their full potential. The accuracy of interferometric feedback also relies on the stable refractive index environment. Changes in temperature, pressure, humidity, and even the local composition of the air may significantly influence the feedback, which complicates the system configuration, thereby increasing costs. Furthermore, the optical alignment of the interferometer is very stringent, complex and time-consuming. The optical alignment needs to be carried out frequently to compensate for the angular error motions, abbe offset, thermal expansion etc. These features may make it difficult to use in some applications which require nanometre level positioning but at the same time require a low cost, easy-to-calibrate system with non-vacuum environment and operate based on a simple optical path. In particular, optical lithographic systems in which the high intensity laser generates a huge amount of heat and causes significant thermal expansion, may not be suitable to be used in conjunction with interferometric techniques.

### SUMMARY

Various embodiments may relate to a positioning system. The positioning system may include a camera and a computer vision system coupled to the camera. The positioning system may also include an objective and a first piezoelectric stage connected to the objective. The positioning system may also include a second piezoelectric stage configured to hold a mask or two dimensional (2D) lens such that the objective is between the camera and the mask or two dimensional (2D) lens. The positioning system may further include a third piezoelectric stage for holding a sample. The first piezoelectric stage may be configured to move the objective for recording a sample level at a point of the sample such as to determine a gap distance between the sample level and a corresponding lens or mask level, the first piezoelectric stage being further configured to move the objective for recording one or more other sample levels at one or more other points of the sample such as to determine one or more other gap distances, thereby determining a plurality of gap distances. The second piezoelectric stage may be configured to move the mask or two dimensional (2D) lens to achieve a desired gap after the plurality of gap distances are determined. The third piezoelectric stage may be configured to adjust to a desired tilt based on a tilt angle determined based on the plurality of gap distances. The computer vision system may be configured to recognize a surface at the sample level before the sample level is recorded.

Various embodiments may relate to a method of forming a positioning system. The method may include coupling a computer vision system to a camera. The method may also include connecting a first piezoelectric stage to an objective. The method may further include providing a second piezoelectric stage configured to hold a mask or two dimensional (2D) lens such that the objective is between the camera and the mask or two dimensional (2D) lens. The method may additionally include providing a third piezoelectric stage for holding a sample. The first piezoelectric stage may be configured to move the objective for recording a sample level at a point of the sample such as to determine a gap distance between the sample level and a corresponding lens or mask level. The first piezoelectric stage may be further configured to move the objective for recording one or more other sample levels at one or more other points of the sample such as to determine one or more other gap distances, thereby determining a plurality of gap distances. The third piezoelectric stage may be configured to adjust to a desired tilt based on a tilt angle determined based on the plurality of gap distances. The computer vision system may be configured to recognize a surface at the sample level before the sample level is recorded.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 is a schematic illustrating a positioning system according to various embodiments.

FIG. 2 is a schematic illustrating a method of forming a positioning system according to various embodiments.

FIG. 3 shows a schematic of an automatic nano-positioning system according to various embodiments.

FIG. 4 is a schematic illustrating the process on recognizing the lens or mask level (Z1) surface and the sample level (Z2) surface according to various embodiments.

FIG. 5 is a schematic showing a process flow of nano-positioning the two dimensional (2D) lens or mask according to various embodiments.

FIG. 6 shows fabricated 130 nm lines formed by the two-dimensional (2D) lens with the nano-positioning system according to various embodiments.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g. within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the positioning systems are analogously valid for the other positioning systems. Similarly, embodiments described in the context of a method are analogously valid for a positioning system, and vice versa.

Various embodiments may seek to address the issues facing conventional interferometric techniques/systems. Various embodiments may be able to be used in applications which require nanometre accuracy but which require low cost easy-to-calibrate systems operating based on a simple optical path. Various embodiments may be used in lithographic systems.

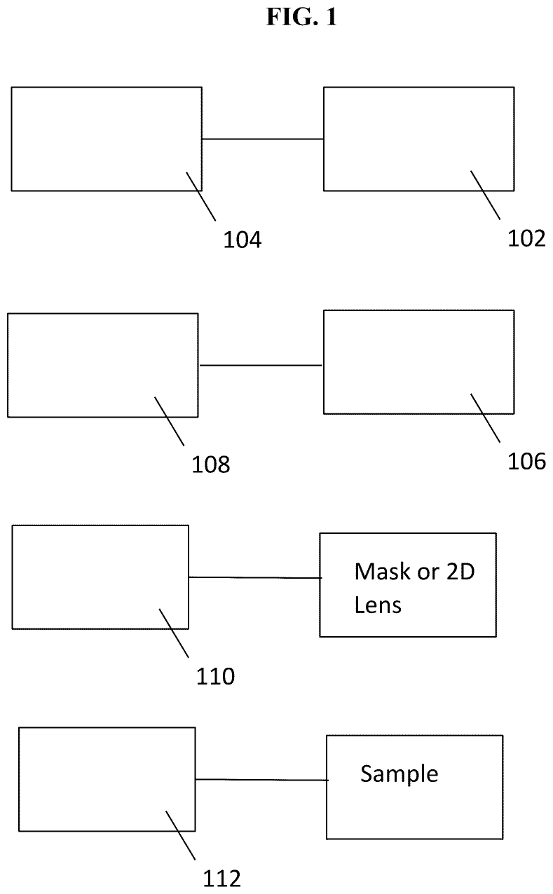

FIG. 1 is a schematic illustrating a positioning system according to various embodiments. The positioning system may be a nano-positioning system. The positioning system may include a camera 102. The positioning system may also include a computer vision system 104 coupled to the camera 102. The positioning system may further include an objective 106. The positioning system may additionally include a first piezoelectric stage 108 connected to the objective 106. The positioning system may also include a second piezoelectric stage 110 configured to hold a mask or two dimensional (2D) lens such that the objective 106 is between the camera 102 and the mask or two dimensional (2D) lens. The positioning system may also include a third piezoelectric stage 112 for holding a sample. The first piezoelectric stage 108 (alternatively referred to as “Piezo Z”) may be configured to move the objective 106 for recording a sample level (i.e. Z2) at a point of the sample such as to determine a gap distance (i.e. Z12) between the sample level (i.e. Z2) and a corresponding lens or mask level (i.e. Z1). The first piezoelectric stage 108 may be further configured to move the objective 106 for recording one or more other sample levels (e.g. Z2′) at one or more other points of the sample such as to determine one or more other gap distances (e.g. Z12′) (i.e. between the one or more other sample levels and corresponding one or other lens or mask levels), thereby determining a plurality of gap distances. The determined gap distance and the determined one or more other gap distances may make up the plurality of gap distances. The second piezoelectric stage 110 (alternatively referred to as “Piezo Cube”) may be configured to move the mask or two dimensional (2D) lens to achieve a desired gap after the plurality of gap distances are determined. The third piezoelectric stage 112 (alternatively referred to as “Piezo Scan Stage”) may be configured to adjust to a desired tilt based on a tilt angle determined based on the plurality of gap distances. The computer vision system 112 may be configured to recognize a surface at the sample level before the sample level is recorded.

In other words, the positioning system may include a camera 102, a computer vision system 104 configured to communicate with the camera 104, an objective 106, a first piezoelectric stage 108 connected, e.g. physically connected, to the objective 106, a second piezoelectric stage 110 configured to hold either a mask or a 2D lens, and a third piezoelectric stage 112 configured to hold a sample. The first piezoelectric stage 108 may be configured to move the objective 106 vertically (after recording a mask or lens level, i.e. Z1) until the computer vision system 112 determines that the surface of the sample can be recognized. Upon the computer vision system 112 determining that the surface of the sample can be recognized, the sample level (i.e. Z2) is recorded. The gap distance may be determined based on the mask or lens level (Z1) and the sample level (Z2). Multiple gap distances at different points of the sample and corresponding points of the mask or the 2D lens may be determined. The first piezoelectric stage 108 may be used to move the objective 106 for recording each pair of sample level and the corresponding mask or level. Based on the multiple gap distances, the second piezoelectric stage 110 may then move the mask or the 2D lens until a desired gap between the mask or the 2D lens and the sample is achieved. Also based on the multiple gap distances, a tilt angle may be determined, and the third piezoelectric stage 112 may adjust to a desired tilt based on the tilt angle determined.

For avoidance of doubt, FIG. 1 seeks to illustrate some features according to various embodiments, and is not intended to limit, for instance, the shape, size, arrangement, orientation etc. of the various components.

The computer vision system 104 may be coupled to the camera 102 via a wired connection or a wireless connection.

In various embodiments, the first piezoelectric stage 108 may be in direct physical contact with the objective 106, or may be connected to the objective 106 via one or more mechanical means/linkages. The first piezoelectric stage 108 may be connected to the objective 106 such that movement of the first piezoelectric stage 108 may cause the objective 106 to move.

In various embodiments, the objective 106 may be configured to switch between a plurality of lenses of different magnifications. The objective 106 may be configured to switch from a first lens of a first magnification (e.g. 10×) to a second lens of a second magnification (e.g. 100×) higher than the first magnification after the computer vision system 104 fails to recognize a surface at the lens or mask level. The computer vision system 104 may be configured to recognize the surface at the lens or mask level before the lens or mask level is recorded.

In various embodiments, the positioning system may be configured to record the corresponding lens or mask level before moving the objective 106 for recording the sample level.

Each of the first piezoelectric stage 108, the second piezoelectric stage 110 and/or the third piezoelectric stage 112 may be or may include one or more piezoelectric actuators.

In various embodiments, the positioning system may include a storage unit, e.g. a memory unit or hard drive configured to record the sample level and the lens or mask level. The storage unit may be coupled to the camera 102 or to the computer vision system 104, or may be part of the camera 102 or the computer vision system 104. In various embodiments, the positioning system may include a processor. The processor may be configured to calculate or determine the plurality of gap distances between the lens or mask level and the sample level. The processor may be configured to calculate or determine the tilt angle, and an average of the plurality of gap distances. The processor may be configured to determine whether the tilt angle falls within a predetermined threshold range. The processor may also be configured to control the movement of the first piezoelectric stage 108, the second piezoelectric stage 110 and the third piezoelectric stage 112. The processor may be configured to determine whether an average of the plurality of gap distances is smaller or larger than the desired gap.

In various embodiments, the first piezoelectric stage 108 may be configured to move the objective 106 towards the sample level (Z2) (i.e. towards the third piezoelectric stage 112) after the corresponding lens or mask level (Z1) is recorded. In various embodiments, the first piezoelectric stage 108 may be configured to move the objective 106 towards the corresponding lens or mask level (Z1) (i.e. towards the camera 102) after the computer vision system 104 fails to recognize the surface at the sample level.

In various embodiments, the first piezoelectric stage 108 may be configured to move the objective 106 back to the corresponding lens or mask level (Z1) after the sample level (Z2) has been recorded.

In various embodiments, the positioning system may further include the mask or two dimensional (2D) lens. The mask or two dimensional (2D) lens may include a marker. The computer vision system (104) may be configured to recognize the marker.

In various embodiments, the second piezoelectric stage 110 may be configured to move the mask or two dimensional (2D) lens towards the objective 106 after an average of the plurality of gap distances is determined to be smaller than the desired gap. In various embodiments, the second piezoelectric stage 110 may be configured to move the mask or two dimensional (2D) lens towards the third piezoelectric stage 112 after the average of the plurality of gap distances is determined to be larger than the desired gap.

In various embodiments, the camera 102 may be a charged-coupled device (CCD).

In various embodiments, the sample may be a wafer.

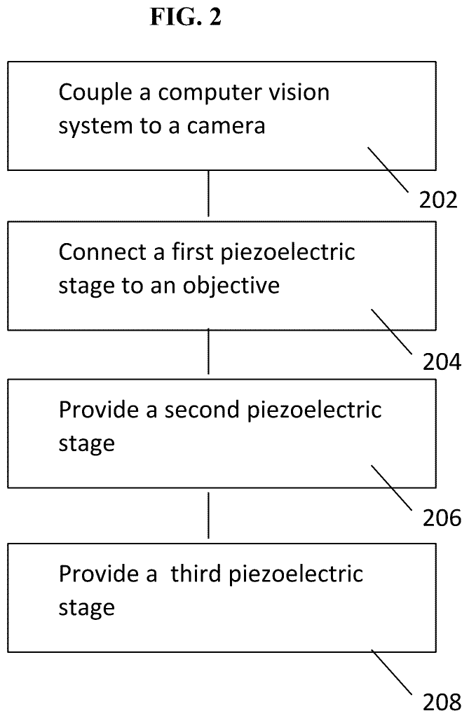

FIG. 2 is a schematic illustrating a method of forming a positioning system according to various embodiments. The method may include, in 202, coupling a computer vision system to a camera. The method may also include, in 204, connecting a first piezoelectric stage to an objective. The method may further include, in 206, providing a second piezoelectric stage configured to hold a mask or two dimensional (2D) lens such that the objective is between the camera and the mask or two dimensional (2D) lens. The method may additionally include, in 208, providing a third piezoelectric stage for holding a sample. The first piezoelectric stage may be configured to move the objective for recording a sample level at a point of the sample such as to determine a gap distance between the sample level and a corresponding lens or mask level. The first piezoelectric stage may be further configured to move the objective for recording one or more other sample levels at one or more other points of the sample such as to determine one or more other gap distances, thereby determining a plurality of gap distances. The third piezoelectric stage may be configured to adjust to a desired tilt based on a tilt angle determined based on the plurality of gap distances. The computer vision system may be configured to recognize a surface at the sample level before the sample level is recorded.

In other words, the method may include assembling the various components such as the camera, the computer vision system, the first piezoelectric stage, the second piezoelectric stage and the third piezoelectric stage.

For avoidance of doubt, FIG. 2 seeks to illustrate some steps according to various embodiments, and is not intended to limit the sequence of the various steps. For instance, step 202 may occur before, after or at the same time as step 204.

In various embodiments, the objective may be configured to switch between a plurality of lenses of different magnifications.

In various embodiments, the positioning system may be configured to record the corresponding lens or mask level before moving the objective for recording the sample level.

In various embodiments, the objective may be configured to switch from a first lens of a first magnification to a second lens of a second magnification higher than the first magnification after the computer vision system fails to recognize a surface at the corresponding lens or mask level. The computer vision system may be configured to recognize the surface at the corresponding lens or mask level before the corresponding lens or mask level is recorded.

In various embodiments, the first piezoelectric stage may be configured to move the objective towards the corresponding lens or mask level after the computer vision system fails to recognize the surface at the sample level.

In various embodiments, the first piezoelectric stage may be configured to move the objective back to the corresponding lens or mask level after the sample level has been recorded.

In various embodiments, the method may include providing the mask or two dimensional (2D) lens. The mask or two dimensional (2D) lens may include a marker. The computer vision system may be configured to recognize the marker.

In various embodiments, the second piezoelectric stage may be configured to move the mask or two dimensional (2D) lens towards the objective after an average of the plurality of gap distances is determined to be smaller than the desired gap. The second piezoelectric stage may be configured to move the mask or two dimensional (2D) lens towards the third piezoelectric stage after the average of the plurality of gap distances is determined to be larger than the desired gap.

In various embodiments, the camera may be a charged-coupled device (CCD).

In various embodiments, the sample may be a wafer.

Various embodiments may relate to a method of operating a positioning system. The method may include providing a positioning system as described herein. The method may include using the camera to capture an image (of a portion) of a surface at the lens or mask level (Z1). The method may also include using the computer vision system to recognize the surface at the lens or mask level (Z1), e.g. recognizing a marker on the surface. The method may include, switching the objective from a first lens of a first magnification to a second lens of a second magnification higher than the first magnification upon the computer vision system failing to recognize the surface at the lens or mask level (Z1). The method may include recording the lens or mask level (Z1) upon the computer vision system recognizing the surface at the lens or mask level (Z1), e.g. recognizing the marker on the surface. The method may further include moving the objective towards the sample for recording a sample level (Z2) using the first piezoelectric stage (piezo Z). The method may also include using the computer vision system to recognize the surface at the sample level (Z2) before recording the sample level. The method may include moving the objective towards the lens or mask level (Z1) using the first piezoelectric stage (piezo Z) upon the computer vision system failing to recognize the surface at the sample level, and thereafter moving the objective towards the sample again for recording the sample level (Z2) using the first piezoelectric stage (piezo Z). The process may be repeated until the computer vision system recognizes the surface at the sample level (Z2).

The method may include moving the objective back to the lens or mask level (Z1) after the sample level (Z2) has been recorded. The method may include determining a gap distance based on the recorded sample level (Z2) at a point of the sample and the corresponding recorded lens or mask level (Z1). The corresponding recorded lens or mask level (Z1) may be at the marker on the surface at the lens or mask level (Z1).

The method may further moving the camera and/or the objective to capture an image of another portion of the surface at the lens or mask level (Z1′). The method may include using the computer vision system to recognize the surface at the lens or mask level (Z1′), e.g. recognizing another marker on the surface. The method may include, switching the objective from a first lens of a first magnification to a second lens of a second magnification higher than the first magnification upon the computer vision system failing to recognize the surface at the lens or mask level (Z1′). The method may include recording the lens or mask level (Z1′) upon the computer vision system recognizing the surface at the lens or mask level (Z1′), e.g. recognizing the other marker on the surface. The method may further include moving the objective towards the sample for recording a sample level (Z2′) using the first piezoelectric stage (piezo Z). The method may also include using the computer vision system to recognize the surface at the sample level (Z2′) (at another point such that the other marker at the lens or mask level (Z1′) corresponds to this other point at the sample) before recording the sample level. The method may include moving the objective towards the lens or mask level (Z1′) using the first piezoelectric stage (piezo Z) upon the computer vision system failing to recognize the surface at the sample level, and thereafter moving the objective towards the sample again for recording the sample level (Z2′) using the first piezoelectric stage (piezo Z). The process may be repeated until the computer vision system recognizes the surface at the sample level (Z2′).

The method may include moving the objective back to the lens or mask level (Z1′) after the sample level (Z2′) has been recorded. The method may include determining a gap distance based on the recorded sample level (Z2′) at the other point of the sample and the corresponding recorded lens or mask level (Z1′). The corresponding recorded lens or mask level (Z1′) may be at the other marker on the surface at the lens or mask level (Z1′). Each corresponding pair of a sample level at a point of the sample and a lens or mask level of the mask or 2D lens may be along a vertical axis, The above steps may be repeated for other markers at the lens or mask level of the mask or 2D lens with corresponding points of the sample at the sample level.

The method may include determining a plurality of gap distances (e.g. Z12, Z12′ etc) between a plurality of lens or mask levels (e.g. Z1, Z1′) and a plurality of corresponding sample levels (e.g. Z2, Z2′) at different points of the sample. The method may also include determining a tilt angle based on the plurality of gap distances. The method may include using the third piezoelectric stage (Piezo Scan Stage) to adjust to a desired tilt upon the positioning system determining that the tilt angle falls outside of a predetermined threshold range.

The method may further include determining whether to move the mask or 2D lens (e.g. by moving or using the second piezoelectric stage (Piezo Cube)) upwards (i.e. towards the objective) or downwards (i.e. towards the third piezoelectric stage) after the plurality of gap distances are determined (and after determining that the tilt angle falls within the predetermined threshold range). The method may include determining an average of the plurality of gap distances.

The method may further include moving the mask or 2D lens upwards (i.e. towards the objective) after an average of the plurality of gap distances is determined to be smaller than the desired gap. The method may include moving the mask or 2D lens downwards (i.e. towards the third piezoelectric stage) after the average of the plurality of gap distances is determined to be larger than the desired gap.

In order to utilize a 2D lens or mask for high-resolution scanning optical confocal imaging and optical lithography, the gap distance between the lens or mask and the sample may need to be precisely determined. Due to the size of the 2D lens or mask, the gap distance may be in a scale of tens of micro-meters for high numerical aperture (NA) arrangement, which requires nanometre-level accuracy in all six degrees of freedom (X, Y, Z, yaw, pitch, and roll) to make sure that the well-formed focal spot can be positioned within the volume of the sample for accurate focusing and direct laser writing. Besides, the mask exposure can be also implemented and well optimized with the precisely positioned gap distance and parallelism. By employing machine vision with high NA objective lens and the piezoelectric motion technology, automatic recognition of the surfaces and positioning of the mask or 2D lens to achieve the required gap distance with nanometre accuracy may be achieved.

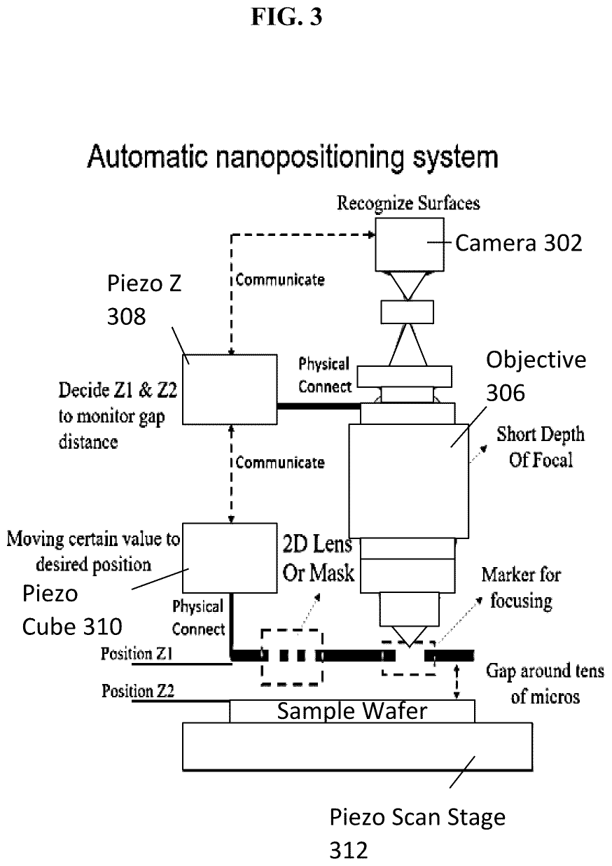

FIG. 3 shows a schematic of an automatic nano-positioning system according to various embodiments. The system may include a first piezoelectric stage 308 (Piezo Z), a second piezoelectric stage 310 (Piezo Cub) and a third piezoelectric stage 312 (Piezo Scan Stage). The system may also include the camera 302 and the objective 306. The computer vision system coupled to the camera is not shown in FIG. 3. The camera 302 and the objective 306 may make up a microscope. The piezoelectric stages 308, 310, 312 and the microscope may not only be used for positioning, but may also be core components for running applications such as imaging and optical lithography using the 2D lens or mask.

The first piezoelectric stage 308 (Piezo Z) may be physically connected to the objective 306. On the other hand, the second piezoelectric stage 310 (Piezo Cube) may be used for the 2D lens or mask. As shown in FIG. 3, the 2D lens or mask may be physically connected or attached to second piezoelectric stage 310 (Piezo Cube). The third piezoelectric stage 312 (Piezo Scan stage) may be used to hold the sample, e.g. a wafer, for implementing applications such as imaging and optical lithography. The sample or wafer may be placed on the third piezoelectric stage 312 (Piezo Scan stage). The camera 302 and the machine vision system may not require additional components such as a laser for interferometric feedback, thereby simplifying the optical path.

The automatic nano-positioning system may be configured to determine the gap distances (corresponding to different points of the sample) between the lens or mask level (Z1) and the sample level (Z2). The gap distances may typically be around tens of micrometres. The automatic nano-positioning system may also be configured to automatically move (i.e. without manual input from a user) the mask or 2D lens after determining the gap distances.

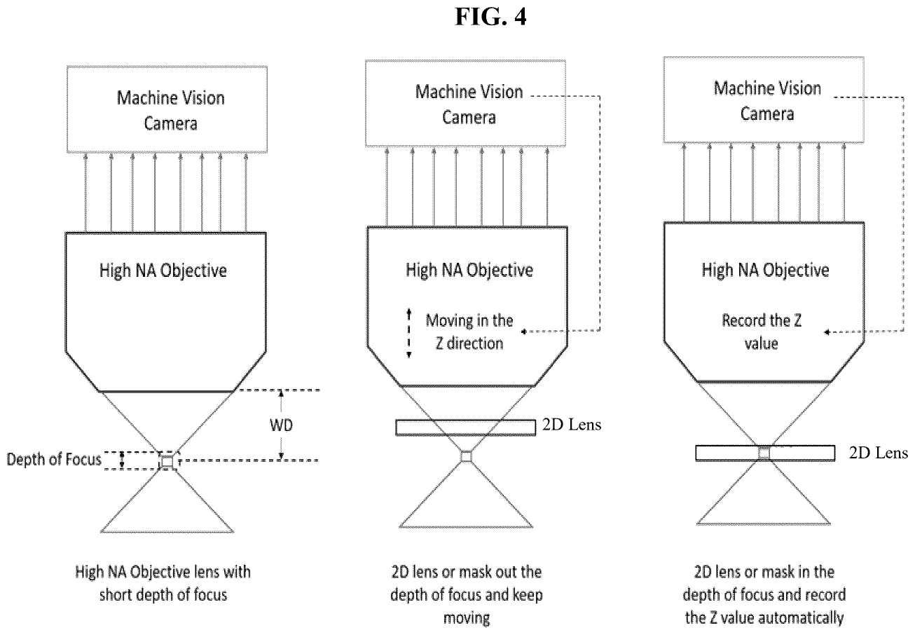

FIG. 4 is a schematic illustrating the process on recognizing the lens or mask level (Z1) surface and the sample level (Z2) surface according to various embodiments. FIG. 4 shows the methodology of recognizing the Z1 and Z2 surfaces with high numerical aperture (NA) objective. Due to the fundamental optical principles, a high magnification and a high NA objective may have a short depth of focus, which may be less than 200 nm. This may mean that a clear image of the surface may only appear in this range. As the first piezoelectric stage configured to move the objective may be capable of small adjustments (of 20 nm or smaller), with optimization of the camera and the computer vision system, a positioning accuracy of 20 nm may be achieved.

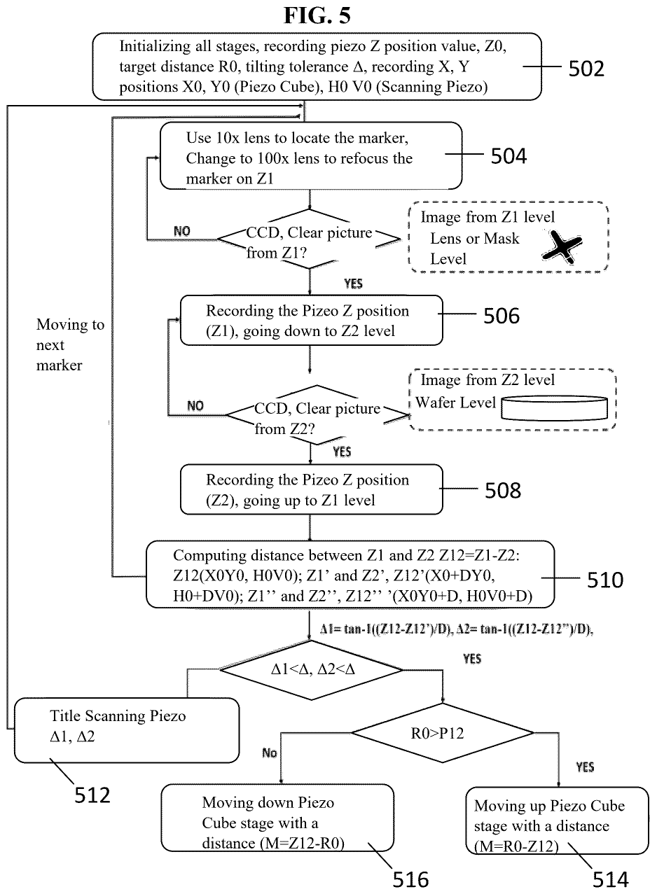

FIG. 5 is a schematic showing a process flow of nano-positioning the two dimensional (2D) lens or mask according to various embodiments. The method may include, in 502, initializing all the piezoelectric stages. The method may also include, in 504, using the computer vision system to recognize the surface at the lens or mask level (Z1), e.g. recognizing a marker on the surface, captured by the camera coupled to the computer vision system. The method may include, switching the objective from a first lens of a first magnification (e.g. 10×) to a second lens of a second magnification (e.g. 100×) higher than the first magnification upon the computer vision system failing to recognize the surface at the lens or mask level (Z1).

The method may include, in 506, recording the lens or mask level (Z1) upon the computer vision system recognizing the surface at the lens or mask level (Z1), e.g. recognizing the marker on the surface. The method may further include moving the objective towards the sample for recording a sample level (Z2) using the first piezoelectric stage (piezo Z). The method may also include using the computer vision system to recognize the surface at the sample level (Z2) before recording the sample level. The method may include moving the objective towards the lens or mask level (Z1) using the first piezoelectric stage (piezo Z) upon the computer vision system failing to recognize the surface at the sample level, and thereafter moving the objective towards the sample again for recording the sample level (Z2) using the first piezoelectric stage (piezo Z). The process may be repeated until the computer vision system recognizes the surface at the sample level (Z2).

The method may include, in 508, moving the objective back to the lens or mask level (Z1) after the sample level (Z2) has been recorded. The method may include, in 510, determining a gap distance (Z12) based on the recorded sample level (Z2) at a point of the sample and the corresponding recorded lens or mask level (Z1). The corresponding recorded lens or mask level (Z1) may be at the marker on the surface at the lens or mask level (Z1).

As shown in FIG. 5 under “Moving to next marker”, the method may further moving the camera and/or the objective to capture an image of another portion of the surface at the lens or mask level (Z1′). The method may include using the computer vision system to recognize the surface at the lens or mask level (Z1′), e.g. recognizing another marker on the surface. The method may include, switching the objective from a first lens of a first magnification (e.g. 10×) to a second lens of a second magnification (e.g. 100×) higher than the first magnification upon the computer vision system failing to recognize the surface at the lens or mask level (Z1′). The method may include recording the lens or mask level (Z1′) upon the computer vision system recognizing the surface at the lens or mask level (Z1′), e.g. recognizing the other marker on the surface. The method may further include moving the objective towards the sample for recording a sample level (Z2′) using the first piezoelectric stage (piezo Z). The method may also include using the computer vision system to recognize the surface at the sample level (Z2′) (at another point such that the other marker at the lens or mask level (Z1′) corresponds to this other point at the sample) before recording the sample level. The method may include moving the objective towards the lens or mask level (Z1′) using the first piezoelectric stage (piezo Z) upon the computer vision system failing to recognize the surface at the sample level, and thereafter moving the objective towards the sample again for recording the sample level (Z2′) using the first piezoelectric stage (piezo Z). The process may be repeated until the computer vision system recognizes the surface at the sample level (Z2′).

The method may include moving the objective back to the lens or mask level (Z1′) after the sample level (Z2′) has been recorded. The method may include determining a gap distance based on the recorded sample level (Z2′) at the other point of the sample and the corresponding recorded lens or mask level (Z1′). The corresponding recorded lens or mask level (Z1′) may be at the other marker on the surface at the lens or mask level (Z1′). Each corresponding pair of a sample level at a point of the sample and a lens or mask level of the mask or 2D lens may be along a vertical axis,

The above steps may be repeated for other markers at the lens or mask level of the mask or 2D lens with corresponding points of the sample at the sample level.

The method may include determining a plurality of gap distances (e.g. Z12, Z12′, Z12″ etc) between a plurality of lens or mask levels (e.g. Z1, Z1′, Z″) and a plurality of corresponding sample levels (e.g. Z2, Z2′, Z2″) at different points of the sample.

The method may also include determining a tilt angle (Δ1, Δ2) based on the plurality of gap distances. The method may include, in 512, using the third piezoelectric stage (Piezo Scan Stage) to adjust to a desired tilt upon the positioning system determining that the tilt angle falls outside of a predetermined threshold range (Δ1 or Δ2>Δ).

The method may further include determining whether to move the mask or 2D lens (e.g. by moving or using the second piezoelectric stage (Piezo Cube)) upwards (i.e. towards the objective) or downwards (i.e. towards the third piezoelectric stage) after the plurality of gap distances are determined (and after determining that the tilt angle falls within the predetermined threshold range, i.e. Δ1<Δ, Δ2<Δ). The method may include determining an average of the plurality of gap distances (P12).

The method may further include, in 514, moving the mask or 2D lens upwards (i.e. towards the objective) after an average of the plurality of gap distances (P12) is determined to be smaller than the desired gap (R0). The second piezoelectric stage (Piezo Cube) may move upwards by a value (M) equivalent to a difference between the desired gap (R0) and the average of the plurality of gap distances (Z12).

The method may include, in 516, moving the mask or 2D lens downwards (i.e. towards the third piezoelectric stage) after the average of the plurality of gap distances (P12) is determined to be larger than the desired gap (R0). The second piezoelectric stage (Piezo Cube) may move downwards by a value (M) equivalent to a difference between the average of the plurality of gap distances (Z12) and the desired gap (R0).

The determination of the plurality of gap distances, the calculation of the average of the plurality of gap distances as well as the difference with the desired gap may be carried out automatically.

For validating the nano-positioning system, a 2D lens with NA of 0.8 and working wavelength of 266 nm may be tested with the system for direct laser writing applications. The working distance of this 2D lens may be set as 30 μm. Due to the short depth of focus ~200 nm of this 2D lens, the positioning accuracy has to be at least 50 nm to maintain the quality of the lithography considering the alignment data from commercial stepper, such ASML/300C.

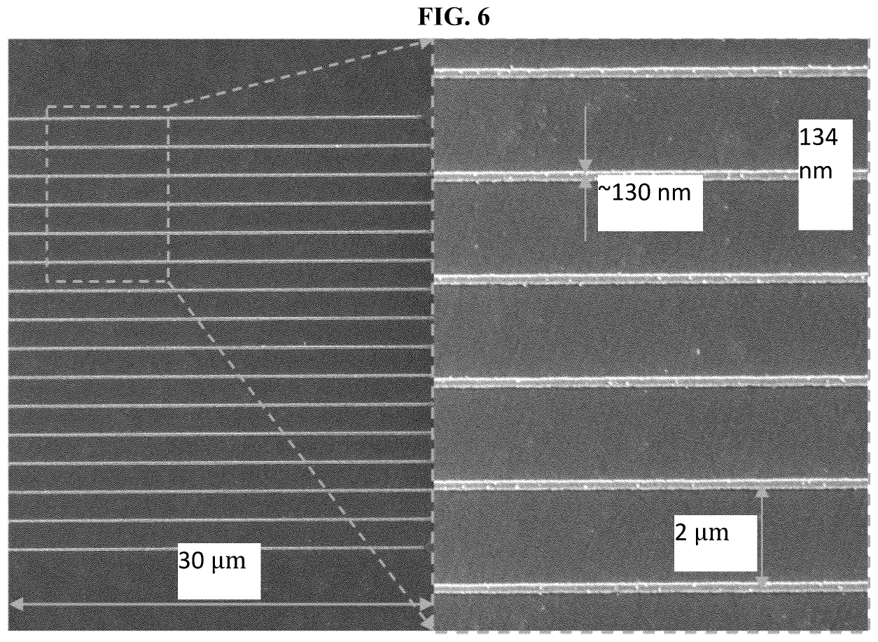

FIG. 6 shows fabricated 130 nm lines formed by the two-dimensional (2D) lens with the nano-positioning system according to various embodiments. 130 nm lines may mean that k1 factor is only 0.39 based on Rayleigh criterion equation. This k1 value indicates a very high lithography quality and may be only achieved with a nanometre-level accuracy nano-positioning. Accordingly, various embodiments described herein may be suitable for 2D lens related applications.

Various embodiments may relate to a nano-positioning system for optical applications using flat lens or mask, such as optical lithography and imaging. Various embodiments may relate to a method of designing nano-positioning system for 2D lens or mask to do optical lithography and imaging. Various embodiments may relate to a process flow for nano-positioning to reach desired parallelism and gap distance. Various embodiments may relate to a method of using machine vision feedback to align 2D lenses and mask automatically with nanometre accuracy. Various embodiments may relate to a method of using high NA microscope system for high accuracy recognition.

Nano-positioning process is mostly developed by interferometric techniques, which rely on the interference of the electromagnetic waves to determine the distance. The physical principle involved would mean that this technique is very sensitive to the environmental optical index, the alignment of optical path and the stability of light source. It would need an additional light source and motion system to implement the function. The features make the system complex, costly and hard to maintain. In contrast, various embodiments use machine vision feedback to drive the motion system. No additional hardware, e.g. laser, is required. The optical path may be a simple microscope setup. The use of machine vision feedback as compared to interferometric feedback may offer costs and product landing advantages. Various embodiments may achieve any desired gap distance positioning in micro-level with a sub-50 nm accuracy which is comparable with interferometric techniques. Besides, the machine vision system may be trained to automatically identify certain markers and samples, which helps to make the system more automated and intelligent.

There is currently no available system on the market for the nano-positioning of 2D lens or mask (level 1) with certain gap distance with wafer or sample (level 2). Most systems are designed to do one-level alignment. Various embodiments may be designed for two-level alignment, which could be used for various 2D lenses. Applications may include, but are not limited to, optical lithography and imaging. With more 2D lenses being introduced into the market, various embodiments may be required for testing and validation.

The next phase of optics for consumer electronics is flat optics which show an overwhelming advantage in performance compared with traditional optics. Most of these flat optics require more advanced optical lithography resolution to 100-300 nm. There is no economical solution in the market currently. Various embodiments may be a 2D lens enabled system which may achieve a resolution of 100-300 nm and may be key to entering the camera optics market to drive “flat transformation”. Due to the short working distance (tens of microns) of the 2D lens, there is no available system on the market that can do the 2-level positioning of 2D lens with wafer. Various embodiments may achieve any desired gap distance positioning in micro-level with a sub-50 nm accuracy.

Due to the 2-level alignment technology, various embodiments may also be used for mask alignment applications. Compared with the traditional mask aligner MA/BA Gen4 from SUSS with 500 nm accuracy and only contact and proximity modes, various embodiments allow for the distance between the mask and wafer to be easily adjusted for any distance (in microns) with sub-50 nm accuracy to achieve optimized results.

Various embodiments may also be used for any application which requires accurate gap positioning such as near-field sensing and imaging.

1. A positioning system comprising:
a camera;
a computer vision system coupled to the camera;
an objective;
a first piezoelectric stage connected to the objective;
a second piezoelectric stage configured to hold a mask or two dimensional (2D) lens such that the objective is between the camera and the mask or two dimensional (2D) lens; and
a third piezoelectric stage for holding a sample;
wherein the first piezoelectric stage is configured to move the objective for recording a sample level at a point of the sample such as to determine a gap distance between the sample level and a corresponding lens or mask level, the first piezoelectric stage being further configured to move the objective for recording one or more other sample levels at one or more other points of the sample such as to determine one or more other gap distances, thereby determining a plurality of gap distances;
wherein the second piezoelectric stage is configured to move the mask or two dimensional (2D) lens to achieve a desired gap after the plurality of gap distances are determined;
wherein the third piezoelectric stage is configured to adjust to a desired tilt based on a tilt angle determined based on the plurality of gap distances; and
wherein the computer vision system is configured to recognize a surface at the sample level before the sample level is recorded.

2. The positioning system according to claim 1, wherein the objective is configured to switch between a plurality of lenses of different magnifications.

3. The positioning system according to claim 1 wherein the positioning system is configured to record the corresponding lens or mask level before moving the objective for recording the sample level.

4. The positioning system according to claim 1,
wherein the objective is configured to switch from a first lens of a first magnification to a second lens of a second magnification higher than the first magnification after the computer vision system fails to recognize a surface at the corresponding lens or mask level; and
wherein the computer vision system is configured to recognize the surface at the corresponding lens or mask level before the corresponding lens or mask level is recorded.

5. The positioning system according to claim 1, wherein the first piezoelectric stage is configured to move the objective towards the corresponding lens or mask level after the computer vision system fails to recognize the surface at the sample level.

6. The positioning system according to claim 1, wherein the first piezoelectric stage is configured to move the objective back to the corresponding lens or mask level after the sample level has been recorded.

7. The positioning system according to claim 1, further comprising:
the mask or two dimensional (2D) lens;
wherein the mask or two dimensional (2D) lens comprises a marker; and
wherein the computer vision system is configured to recognize the marker.

8. The positioning system according to claim 1,
wherein the second piezoelectric stage is configured to move the mask or two dimensional (2D) lens towards the objective after an average of the plurality of gap distances is determined to be smaller than the desired gap; and
wherein the second piezoelectric stage is configured to move the mask or two dimensional (2D) lens towards the third piezoelectric stage after the average of the plurality of gap distances is determined to be larger than the desired gap.

9. The positioning system according to claim 1, wherein the camera is a charged-coupled device (CCD).

10. The positioning system according to claim 1, wherein the sample is a wafer.

11. A method of forming a positioning system, the method comprising:
coupling a computer vision system to a camera;
connecting a first piezoelectric stage to an objective;
providing a second piezoelectric stage configured to hold a mask or two dimensional (2D) lens such that the objective is between the camera and the mask or two dimensional (2D) lens; and
providing a third piezoelectric stage for holding a sample;
wherein the first piezoelectric stage is configured to move the objective for recording a sample level at a point of the sample such as to determine a gap distance between the sample level and a corresponding lens or mask level, the first piezoelectric stage being further configured to move the objective for recording one or more other sample levels at one or more other points of the sample such as to determine one or more other gap distances, thereby determining a plurality of gap distances;
wherein the second piezoelectric stage is configured to move the mask or two dimensional (2D) lens to achieve a desired gap after the plurality of gap distances are determined;
wherein the third piezoelectric stage is configured to adjust to a desired tilt based on a tilt angle determined based on the plurality of gap distances; and
wherein the computer vision system is configured to recognize a surface at the sample level before the sample level is recorded.

12. The method according to claim 11, wherein the objective is configured to switch between a plurality of lenses of different magnifications.

13. The method according to claim 11, wherein the positioning system is configured to record the corresponding lens or mask level before moving the objective for recording the sample level.

14. The method according to claim 11,
wherein the objective is configured to switch from a first lens of a first magnification to a second lens of a second magnification higher than the first magnification after the computer vision system fails to recognize a surface at the corresponding lens or mask level; and
wherein the computer vision system is configured to recognize the surface at the corresponding lens or mask level before the corresponding lens or mask level is recorded.

15. The method according to claim 11, wherein the first piezoelectric stage is configured to move the objective towards the corresponding lens or mask level after the computer vision system fails to recognize the surface at the sample level.

16. The method according to claim 11, wherein the first piezoelectric stage is configured to move the objective back to the corresponding lens or mask level after the sample level has been recorded.

17. The method according to claim 11, further comprising:
providing the mask or two dimensional (2D) lens;
wherein the mask or two dimensional (2D) lens comprises a marker; and
wherein the computer vision system is configured to recognize the marker.

18. The method according to claim 11,
wherein the second piezoelectric stage is configured to move the mask or two dimensional (2D) lens towards the objective after an average of the plurality of gap distances is determined to be smaller than the desired gap; and
wherein the second piezoelectric stage is configured to move the mask or two dimensional (2D) lens towards the third piezoelectric stage after the average of the plurality of gap distances is determined to be larger than the desired gap.

19. The method according to claim 11, wherein the camera is a charged-coupled device (CCD).

20. The method according to claim 11, wherein the sample is a wafer.
